(19) United States
(12) Patent Application Publication
(10) Pub. No.: US 2026/0215104 A1
(43) Pub. Date: Jul. 23, 2026

(54) DISPLAY DEVICE

(71) Applicant: Sharp Display Technology Corporation, Kameyama City, Mie (JP)

(72) Inventor: Satoshi INOUE, Kameyama City. Mie (JP)

(21) Appl. No.: 19/136,501

(22) PCT Filed: Dec. 23, 2022
(86) PCT No.: PCT/JP2022/047626

§ 371 Date: Jun. 6, 2025

(51) Int. Cl. H10K 59/124

(52) U.S. Cl. CPC H10K 59/124

(57) ABSTRACT

A display device in accordance with the present disclosure includes: an organic insulating film formed on a pixel circuit board; a first electrode formed on the organic insulating film; and an edge cover film covering an edge of the first electrode, wherein a first depression at least a part of which does not overlap the edge cover film and the first electrode is formed in the organic insulating film.

### TECHNICAL FIELD

The present disclosure relates to display devices and methods of manufacturing display devices.

### BACKGROUND ART

Patent Literature 1 discloses a structure that includes: an opening in which a pixel-defining film exposes a part of a pixel electrode; and a trap positioned on at least one of sides of the periphery of the pixel electrode, to confine foreign objects on the pixel electrode in the trap during rinsing.

### CITATION LIST

### Patent Literature

Patent Literature 1: Japanese Unexamined Patent Application Publication No. 2007-141838 (Publication Date: Jun. 7, 2007)

### SUMMARY

### Technical Problem

The structure disclosed in Patent Literature 1 is not sufficiently capable of trapping the foreign objects.

### Solution to Problem

The present disclosure, in an aspect thereof, is directed to a display device including: a pixel circuit board; an organic insulating film formed on the pixel circuit board; a first electrode formed on the organic insulating film; and an edge cover film covering an edge of the first electrode, wherein a first depression at least a part of which does not overlap the edge cover film and the first electrode is formed in the organic insulating film.

The present disclosure, in an aspect thereof, is directed to a method of manufacturing a display device, the method including: a step of forming, on a pixel circuit board, an organic insulating film that has a first depression; a step of forming a first electrode on the organic insulating film; and a step of forming an edge cover film that covers an edge of the first electrode and that has a through hole overlapping the first depression.

### Advantageous Effects of Disclosure

The present disclosure, in an aspect thereof, facilitates trapping of foreign objects in the first depression.

### BRIEF DESCRIPTION OF DRAWINGS

FIG. 1 is a plan view of a structure of a display device in accordance with an embodiment of the present disclosure.

FIG. 2 is a cross-sectional view of an exemplary structure of a display unit shown in FIG. 1.

FIG. 3 is a plan view of an exemplary arrangement of depressions in the display unit shown in FIG. 1.

FIG. 4 is a plan view of an exemplary arrangement of depressions in the display unit shown in FIG. 1.

FIG. 5 is a plan view of an exemplary arrangement of depressions in the display unit shown in FIG. 1.

FIG. 6 is a plan view of an exemplary arrangement of depressions in the display unit shown in FIG. 1.

FIG. 7 is a plan view of an exemplary arrangement of depressions in the display unit shown in FIG. 1.

FIG. 8 is a plan view of an exemplary arrangement of depressions in the display unit shown in FIG. 1.

FIG. 9 is a flow chart representing an exemplary method of manufacturing a display device in accordance with an embodiment of the present disclosure.

FIG. 10 is a cross-sectional view illustrating an exemplary method of manufacturing a display device in accordance with an embodiment of the present disclosure.

FIG. 11 is a cross-sectional view of a variation example of the structure of the display unit shown in FIG. 1.

FIG. 12 is a flow chart representing a variation example of a method of manufacturing a display device in accordance with an embodiment of the present disclosure.

FIG. 13 is a cross-sectional view illustrating a variation example of a method of manufacturing a display device in accordance with an embodiment of the present disclosure.

FIG. 14 is a diagram representing a plan-view photograph of a subpixel in accordance with Example 1.

FIG. 15 is a cross-sectional view of an exemplary structure of a display unit in a display device in accordance with an embodiment of the present disclosure.

FIG. 16 is a flow chart representing an exemplary method of manufacturing a display device in accordance with an embodiment of the present disclosure.

FIG. 17 is a cross-sectional view illustrating an exemplary method of manufacturing a display device in accordance with an embodiment of the present disclosure.

FIG. 18 is a cross-sectional view of an exemplary structure of a display unit in a display device in accordance with an embodiment of the present disclosure.

FIG. 19 is a flow chart representing a variation example of a method of manufacturing a display device in accordance with an embodiment of the present disclosure.

FIG. 20 is a cross-sectional view illustrating a variation example of a method of manufacturing a display device in accordance with an embodiment of the present disclosure.

FIG. 21 is a cross-sectional view of a display unit in accordance with a comparative example in which there are provided no depressions for capturing foreign objects in an organic insulating film.

FIG. 22 is a diagram representing a plan-view photograph of a subpixel in accordance with a comparative example.

### DESCRIPTION OF EMBODIMENTS

### Embodiment 1

### Structure of Display Device

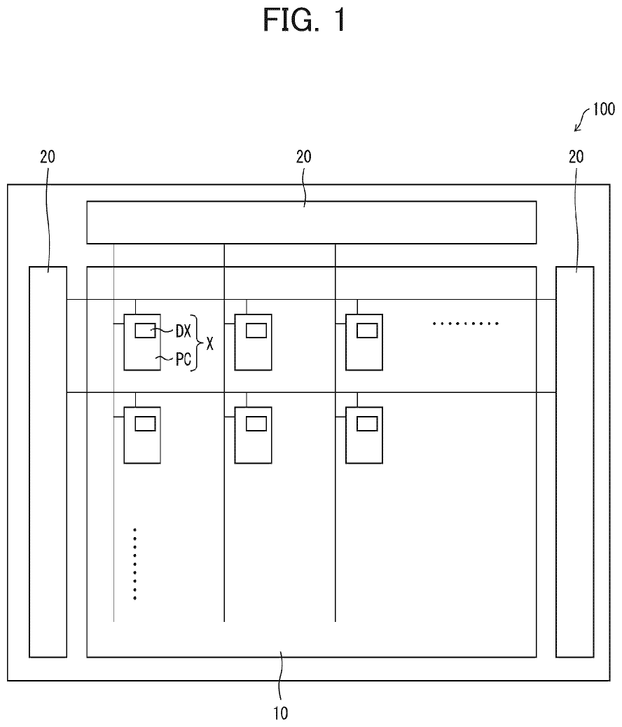

FIG. 1 is a plan view of a structure of a display device in accordance with an embodiment of the present disclosure. Referring to FIG. 1, a display device 100 includes: a display unit 10 including a plurality of subpixels X; and a drive circuit 20 for driving the display unit 10. Each subpixel X includes a pixel circuit PC and a light-emitting element DX.

### Cross-sectional Structure of Display Unit

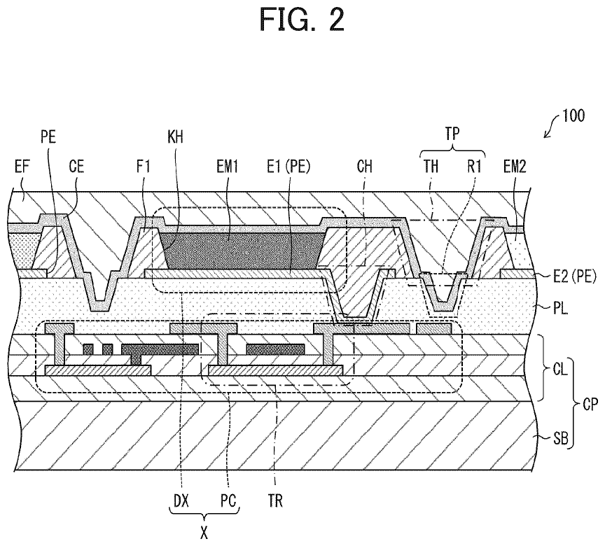

FIG. 2 is a cross-sectional view of an exemplary structure of the display unit shown in FIG. 1. Referring to FIG. 2, the display device 100 includes: a pixel circuit board CP; an organic insulating film PL formed on the pixel circuit board CP; a first electrode E1 formed on the organic insulating film PL; and an edge cover film F1 covering an edge of the first electrode E1, wherein in the organic insulating film PL, there is formed a first depression R1 at least a part of which does not overlap the edge cover film F1 and the first electrode E1. The first electrode E1 may be one of a plurality of pixel electrodes PE. In the present disclosure, the position of the organic insulating film PL relative to the pixel circuit board CP will be referred to as the “upper side,” irrespective of the posture of the display device 100. A “plan view” in the present disclosure indicates that an object is viewed in a line of sight that is parallel to the normal to the pixel circuit board CP (including see-through views).

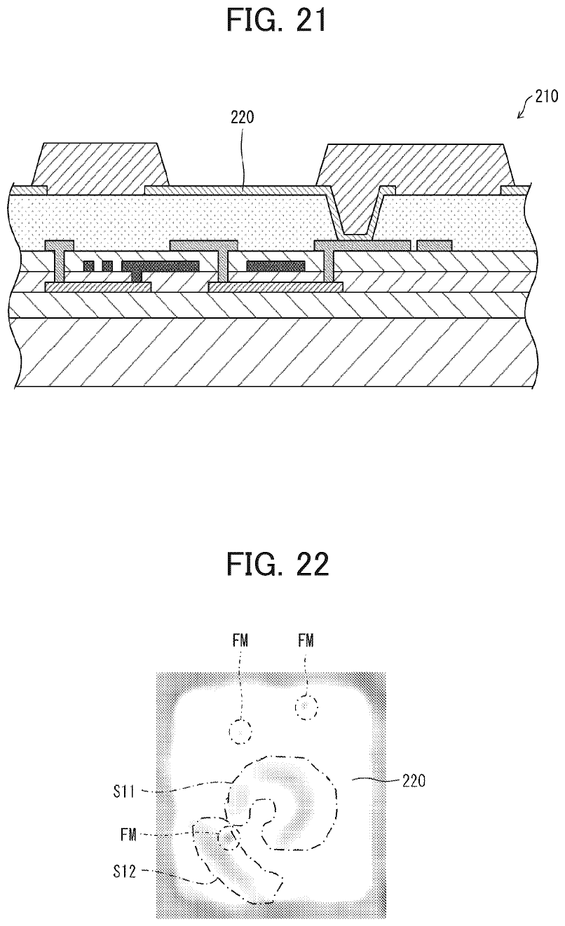

FIG. 21 is a cross-sectional view of a display unit in accordance with a comparative example in which there are provided no depressions for capturing foreign objects in the organic insulating film. Foreign objects can easily form, move, and adhere to the most depressed parts of a product in process at all times in the manufacture. For example, SUS-type foreign objects are produced by manufacturing equipment, and when pixel electrodes are formed, Ag-type foreign objects that originate in the electrode material, foreign objects that originate in the planarization film, and foreign objects that originate in the vapor deposition material are produced. The produced foreign objects are transported in, for example, the rinsing of the substrate, the application of resist, and air blowing. During this transport, the foreign objects readily move over low steps, but not over high steps. Therefore, the foreign objects readily collect and adhere to the most depressed parts. In the comparative example shown in FIG. 21, the most depressed parts of the product in process are positioned on or above a pixel electrode 220, so that the foreign objects are likely to adhere onto or somewhere above the pixel electrode 220 (“intra-pixel adhesion” of foreign objects).

Referring again to FIG. 2, in the structure in accordance with the present disclosure, the first depression R1 has a bottom that is at a lower level than the first electrode E1. Therefore, foreign objects are readily captured in a trap TP, and the captured foreign objects are unlikely to move out the trap TP. Therefore, the present disclosure is capable of reducing foreign objects positioned on the first electrode E1, thereby improving the yield and display quality of the display device 100.

The pixel circuit board CP includes a support substrate SB and a circuit layer CL provided on the support substrate SB. The pixel circuit PC may be provided inside the circuit layer CL. The organic insulating film PL is a resin film serving as a planarization film. The organic insulating film PL may be made of photosensitive resin. The organic insulating film PL may contain any one or more of, for example, phenolic resin, novolac-type resin, polyimide-type resin, acrylic resin, photosensitive-agent-containing resin, and coupling-agent-containing resin.

The bottom of the first depression R1 may be positioned inside the organic insulating film PL. In other words, the first depression R1 may not run through the organic insulating film PL. The first depression R1 may be positioned in the vicinity of the first electrode E1 in a plan view. The first depression R1 may be tapered downward.

The edge cover film F1 has a through hole TH that overlaps the first depression R1 (in other words, a through hole TH that is spatially continuous with the first depression R1). The through hole TH may be tapered downward. The opening of the first depression R1 may have a smaller area than does the bottom of the through hole TH. The opening of the first depression R1 may have a smaller width than does the bottom of the through hole TH. In such cases, the entire first depression R1 does not overlap the edge cover film. The edge cover film F1 further has a through hole KH that overlaps a central portion of the first electrode E1 in a plan view to expose the central portion of the first electrode E1.

The edge cover film F1 may be a resin film. The edge cover film F1 may be made of photosensitive resin. The edge cover film F1 may contain any one or more of, for example, phenolic resin, novolac-type resin, polyimide-type resin, acrylic resin, photosensitive-agent-containing resin, and coupling-agent-containing resin.

The display device 100 may include a second electrode E2 positioned on the organic insulating film PL. The edge cover film F1 may cover an edge of the second electrode E2, and the first depression R1 may be positioned between the first electrode E1 and the second electrode E2 in a plan view. The second electrode E2 is one of the plurality of pixel electrodes PE.

The display device 100 may include a transistor TR that connects to the first electrode E1 via a contact hole CH that runs through the organic insulating film PL. The transistor TR may be included in the pixel circuit PC. The first depression is positioned so as not to interfere with the contact hole CH.

A light-emitting layer EM1 may be formed so as to overlap the first electrode E1 in a plan view. Furthermore, there may be provided a common electrode CE opposite the first electrode E1, and the light-emitting layer EM1 may be positioned between the first electrode E1 and the common electrode CE. A light-emitting layer EM2 may be formed so as to overlap the second electrode E2 in a plan view, and a light-emitting layer may be formed so as to overlap the other pixel electrodes PE in a plan view. In addition, where necessary, there may be provided functional layers, such as a charge transport layer and a charge injection layer, between the pixel electrodes PE and the common electrode CE. The functional layer may be an organic layer. The functional layer may be provided commonly to the plurality of subpixels X and across the display unit 10. The functional layer may be made of different materials, depending on the subpixels X. In addition, the display unit 10 may include a sealing layer EF covering the common electrode CE.

The light-emitting layers EM1, EM2 may contain an organic light-emitting material and may contain luminous quantum dots. The light-emitting layers EM1, EM2 may have the same peak emission wavelength or different peak emission wavelengths. The display device 100 may include a red-light-emitting red light-emitting layer, a green-light-emitting green light-emitting layer, and a blue-light-emitting blue light-emitting layer.

Therefore, the display unit 10 may include light-emitting elements DX including the light-emitting layer EM1 and with the first electrode E1 as an anode and the common electrode CE as a cathode. In addition, the display unit 10 may include other light-emitting elements DX including the light-emitting layer EM2 and with the second electrode E2 as an anode and the common electrode CE as a cathode. Note that the scope of the present disclosure encompasses structures where the first electrode E1 and the second electrode E2 are cathodes, and the common electrode CE is an anode.

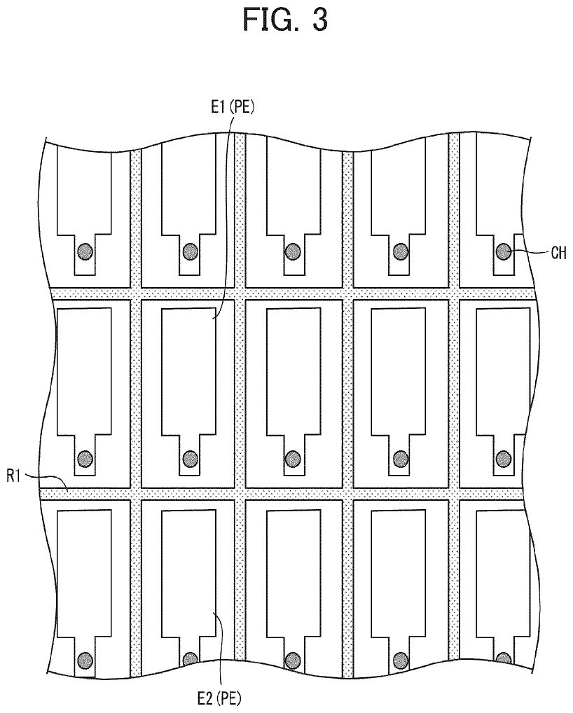

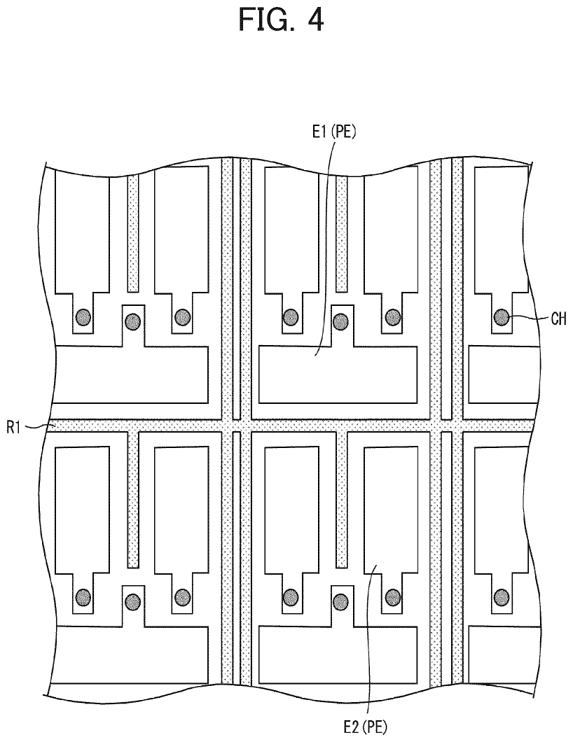

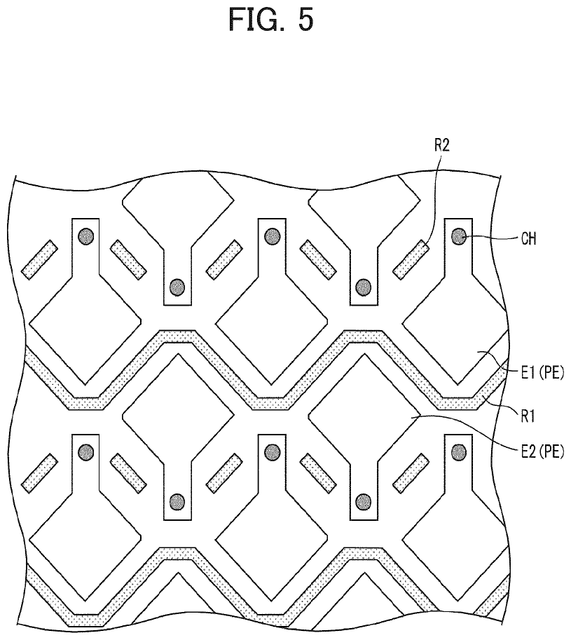

Arrangement 1 of Depressions Each of FIGS. 3, 4, and 5 is a plan view of an exemplary structure of the display unit shown in FIG. 1. As shown in FIGS. 3 and 4, the first depression R1 may surround the first electrode E1. The first depression R1 may surround each pixel electrode PE separately from the other pixel electrodes PE as shown in FIG. 3 and may surround each set of pixel electrodes PE separately from the other pixel electrodes PE as shown in FIG. 4. Referring to FIG. 5, the first depression R1 may be extended from one side of the display unit 10 to the other. In these examples, the first depression R1 divides the display unit 10 into a plurality of regions in a plan view.

The first depression R1 and the through hole TH are tapered downward so that the common electrode CE does not break up easily in the first depression R1 and the through hole TH. Therefore, even when the first depression R1 divides the display unit 10 into a plurality of regions, the common electrode CE can maintain its electrical continuity across the entire display unit 10.

In addition, referring to FIG. 5, in the organic insulating film PL, there may be provided second depressions R2 at least a part of which does not overlap the edge cover film F1 and a first electrode EC in a plan view, and each of the first depression R1 and the second depressions R2 may be shaped like a groove. In the present disclosure, the language, “like a groove,” indicates that the depression has an elongated shape in a plan view, and the elongated shape may include a linear shape, a buckled shape, and a wobbling shape.

Under these circumstances, the first depression R1 and the second depressions R2 may have different lengths. Here, the lengths of the first depression R1 and the second depressions R2 are their dimensions as measured along their extension directions in a plan view respectively. In addition, the extension direction of the first depression and the extension direction of the second depressions may make an angle. In addition, the first electrode EC may be positioned between the first depression R1 and the second depressions R2 in a plan view. In addition, when the first electrode EC is a polygonal, the extension direction of the second depressions R2 may be parallel to one of the sides of the first electrode EC, and the length of the second depressions R2 may be less than or equal to the length of this side.

### Arrangement 2 of Depressions

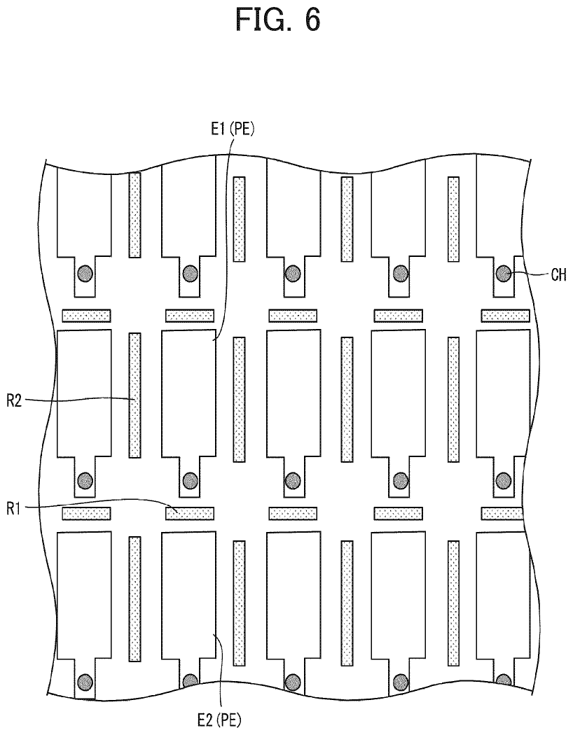

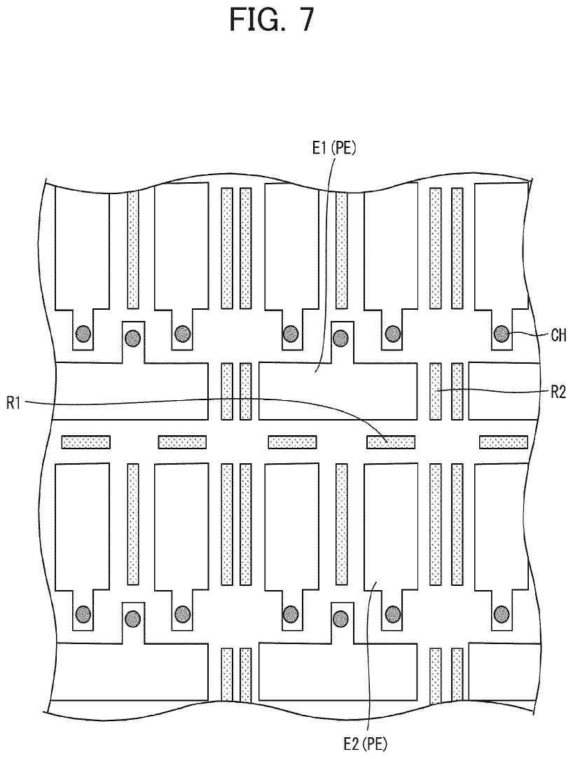

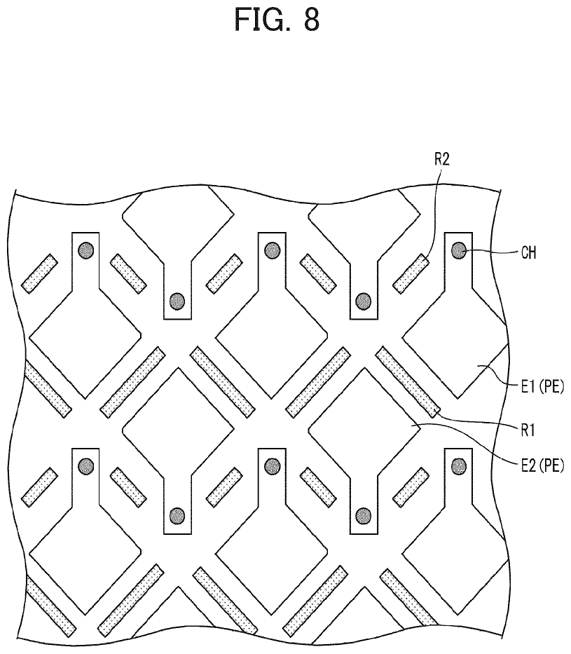

FIGS. 6, 7, and 8 are plan views of an exemplary structure of the display unit shown in FIG. 1. Referring to FIGS. 6 to 8, in the organic insulating film PL, there may be provided second depressions R2 at least a part of which does not overlap the edge cover film F1 and the first electrode EC, and each of the first depression R1 and the second depressions R2 may be shaped like a groove. Under these circumstances, the first depression R1 and the second depressions R2 may have different lengths. In addition, the extension direction of the first depression and the extension direction of the second depressions may make an angle. In addition, the first electrode EC may be positioned between the first depression R1 and the second depressions R2 in a plan view. In addition, when the first electrode EC is a polygonal, the extension direction of the second depressions R2 may be parallel to one of the sides of the first electrode EC, and the length of the second depressions R2 may be less than or equal to the length of this side.

The pixel electrodes PE may be disposed in any arrangement including a PenTile arrangement and a Stripe arrangement, and the first depression R1 and the second depressions R2 may be arranged in accordance with the arrangement of the pixel electrodes PE.

### Method of Manufacturing Display Device

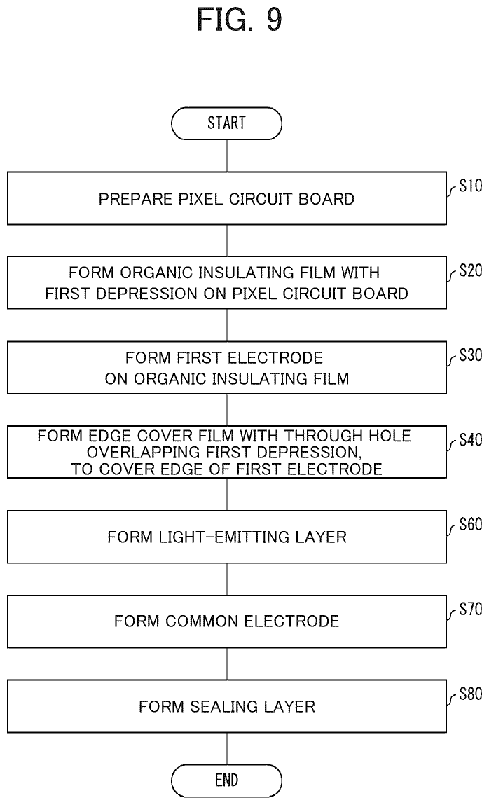

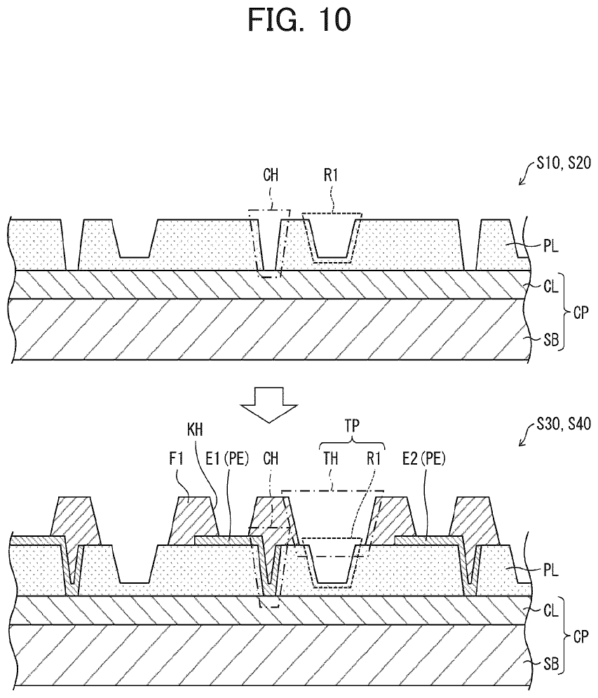

FIG. 9 is a flow chart representing an exemplary method of manufacturing a display device in accordance with an embodiment of the present disclosure. FIG. 10 is a cross-sectional view illustrating an exemplary method of manufacturing a display device in accordance with an embodiment of the present disclosure. Referring to FIGS. 9 and 10, first, the pixel circuit board CP is prepared (step S10), and the organic insulating film PL, which has the first depression R1, is then formed on the pixel circuit board CP (step S20). Step S20 may form the organic insulating film PL with the first depression R1 by applying a photosensitive resin flatly onto the pixel circuit board CP and then subjecting the applied photosensitive resin to photolithography. Alternatively, step S20 may form a flat organic insulating film PL on the pixel circuit board CP and then form the first depression R1 in the organic insulating film PL by etching. Step S20 may form the contact hole CH and the depressions other than the first depression R1 in the organic insulating film PL.

Step S20 preferably forms the first depression R1 so that the first depression R1 does not run through the organic insulating film PL. By the first depression R1 not running through the organic insulating film PL, the organic insulating film PL remains between the bottom of the first depression R1 and the pixel circuit board CP, so that the first depression R1 can be disposed directly above, and in the vicinity of, a conductor. Therefore, the first depression R1 can be disposed irrespective of the arrangement of the electrodes and wires on the pixel circuit board CP, which improves freedom in arranging the first depression R1. Step S20 forms a contact hole so that the contact hole CH can run through the organic insulating film PL.

Therefore, step S20 may adjust the depth of the first depression R1 such that the first depression R1 is less deep than the contact hole CH. When, for example, photolithography is used, step S20 may adjust the depth of the first depression R1 by using a halftone mask or a gray tone. When, for example, etching is used, step S20 may adjust the depth of the first depression R1 on the basis of the etching rate and the etching time.

Subsequently, the first electrode E1 is formed on the organic insulating film PL (step S30). Step S30 may form the first electrode E1 by any method including etching and lift-off. Step S30 may form the electrodes and wires other than the first electrode E1 Subsequently, the edge cover film F1 is formed that has the through hole TH overlapping the first depression R1 and that covers an edge of the first electrode E1 (step S40). Step S40 may form the edge cover film that has the through hole TH by applying a photosensitive resin flatly onto the organic insulating film PL and the first electrode E1 and then subjecting the applied photosensitive resin to photolithography. Alternatively, step S40 may form a flat edge cover film F1 on the organic insulating film PL and the first electrode E1 and form the through hole TH in the organic insulating film PL by etching. Step S40 may form a through hole other than the through hole TH in the edge cover film F1. Step S40 may form the through hole KH in the edge cover film F1.

Subsequently, the light-emitting layer EM1 is formed (step S60), and the common electrode CE is formed (step S70). Step S60 may form the light-emitting layer EM2 other than the light-emitting layer EM1 where necessary. Various functional layers may be formed in a suitable manner between step S50 and step S70. The sealing layer EF may be formed after step S70 (step S80).

### VARIATION EXAMPLE

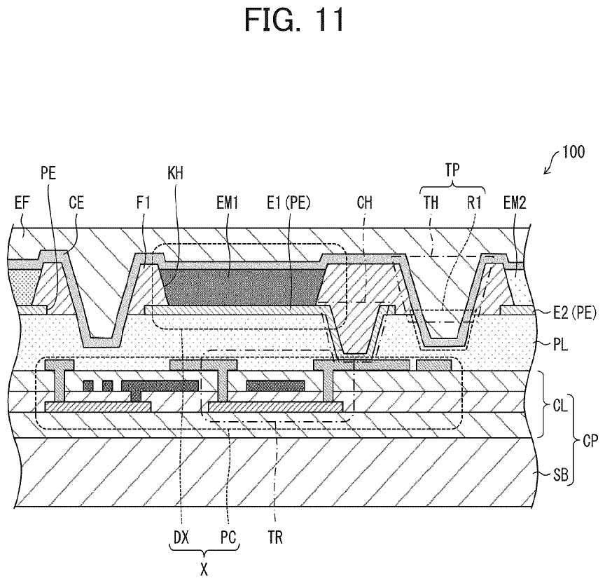

FIG. 11 is a cross-sectional view of a variation example of the structure of the display unit shown in FIG. 1. Referring to FIG. 11, the through hole TH may have a sidewall that is flush with a sidewall of the first depression. Under these circumstances, the area and width of the opening of the first depression R1 are equal to the area and width of the bottom of the through hole TH, and the entire first depression R1 does not overlap the edge cover film.

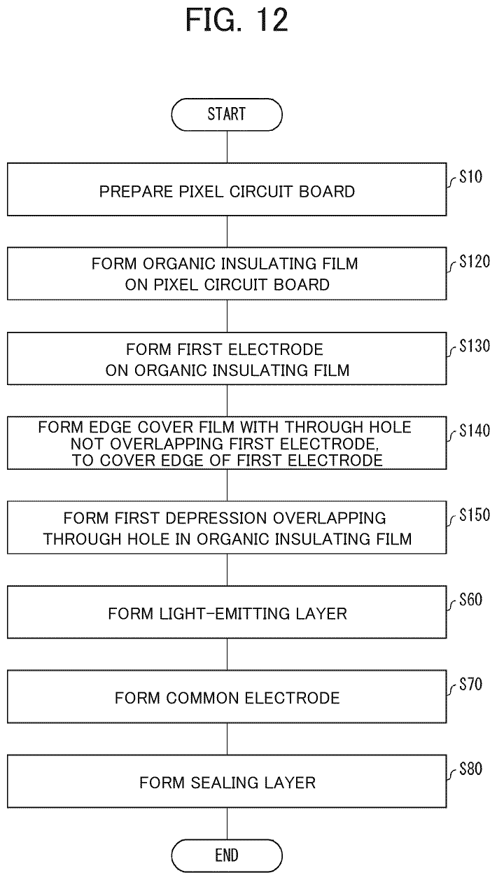

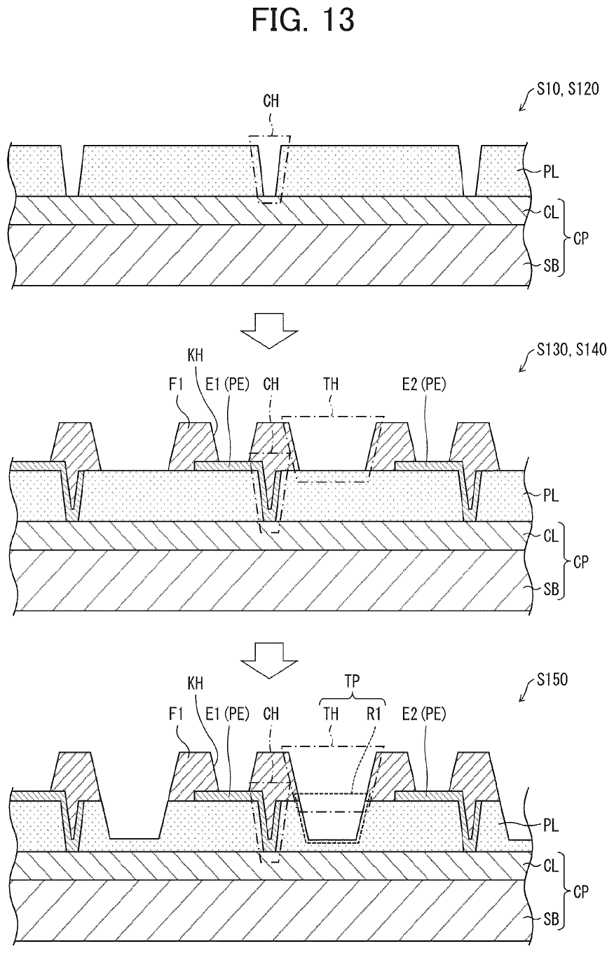

FIG. 12 is a flow chart representing a variation example of a method of manufacturing a display device in accordance with an embodiment of the present disclosure. FIG. 13 is a cross-sectional view illustrating a variation example of a method of manufacturing a display device in accordance with an embodiment of the present disclosure. Referring to FIGS. 12 and 13, first, the pixel circuit board CP is prepared (step S10), and the organic insulating film PL is then formed on the pixel circuit board CP (step S120).

Subsequently, the first electrode E1 is formed on the organic insulating film PL (step S130), and the edge cover film F1 is formed that has the through hole TH not overlapping the first electrode E1 and that covers an edge of the first electrode E1 (step S140). Then, in the organic insulating film PL, the first depression R1 is formed that overlaps the through hole TH (that is spatially continuous with the through hole TH) (step S150). Step S150 may etch the organic insulating film PL by using the edge cover film F1 as an etching mask. Hence, the first depression R1 aligns with the through hole TH, which facilitates increasing the area of the first depression R1 in a plan view. Step S140 and step S150 may be performed in a single etching step. Hence, the through hole TH and the first depression R1 can be easily formed such that the through hole TH has a side face that is flush with a side face of the first depression R1.

Subsequently, steps S60, S70, and S80 are performed.

### Example 1

Referring again to FIGS. 2, 9, and 10, a description is given below of the display device 100 of Example 1 in accordance with the present disclosure. In step S10, first, a glass substrate with a thickness of 0.7 mm, specifically, a 1737 manufactured by Corning Japan K.K., was prepared as the support substrate SB. Foreign objects such as organic materials were removed from the glass substrate by a rinsing method such as IPA ultrasonic rinsing or pure water rinsing. The circuit layer CL was then formed as described in the following.

First, silicon oxide was deposited on the glass substrate by chemical vapor deposition (CVD) to form a film with a thickness of 200 nm to 1 μm as a protective film. Next, an amorphous silicon film was formed as a semiconductor film with a thickness of 50 nm by plasma CVD and heated in an oven. Furthermore, the semiconductor film was laser-annealed in a laser-treatment step, patterned photoresist was formed on the semiconductor film by photolithography, and the semiconductor film was etched by dry etching to remove the photoresist. Hence, a patterned semiconductor film was formed.

In the following description, the process of forming patterned photoresist on a target layer by photolithography and etching the target layer by dry etching to remove the photoresist, thereby patterning the target layer, will be referred to, in an abbreviated manner, as the “patterning of the target layer by dry etching” for convenience.

Next, silicon oxide was deposited to a thickness of 70 nm to 250 nm by CVD to form a gate insulating film. Then, the semiconductor film was subjected to a doping step such as whole-surface doping or channel doping by ion doping. Next, as a gate conductive film, for example, tungsten (W) and molybdenum (Mo) were vapor-deposited across the entire surface and patterned by dry etching. Patterned gate lines were hence formed. Furthermore, the semiconductor film was subjected to various doping steps by ion doping to form thin film transistors (TFTs).

Next, as an interlayer insulating film, silicon oxide was deposited across the entire surface to a thickness of 600 nm by CVD and patterned by dry etching. Contact holes were hence formed in the interlayer insulating film. Next, as a source conductive film, a three-layered film containing titanium (Ti) and aluminum (Al) was formed by sputtering across the entire surface and patterned by dry etching. Patterned source lines were hence formed. Thereafter, heat treatment was performed.

Next, in step S20, a commercially available photosensitive polyimide resin was applied to a thickness of 2 μm by spin-coating as the organic insulating film PL. Then, the contact hole CH was formed by photolithography in those sites where the pixel electrodes PE would be formed in the organic insulating film PL, and the first depression R1 was formed so as to surround the sites where the pixel electrodes PE would be formed. The contact hole CH and the first depression R1 were simultaneously formed by using a halftone mask. The organic insulating film PL, after being subjected to pattern exposure, was developed in an alkaline solution, rinsed in water, and baked to 200 degrees Celsius or higher temperature in an oven.

Next, in step S30, a three-layered film including tin-doped indium oxide (In₂O₃:Sn) films and a silver (Ag) film was formed across the entire surface by sputtering as a pixel electrode layer and patterned by dry etching. The plurality of pixel electrodes PE including the first electrode E1 were hence formed. In the following description, tin-doped indium oxide will be referred to as “indium tin oxide.” The three-layered film was formed by forming a 10-nm thick indium tin oxide film by sputtering, furthermore forming a 100-nm thick silver film by sputtering, and furthermore forming a 10-nm thick indium tin oxide film by sputtering.

Next, in step S40, a photosensitive polyimide resin was applied by spin-coating as the edge cover film F1. Then, the through hole TH overlapping the first depression R1 in a plan view and through holes overlapping central portions of the pixel electrodes PE in a plan view were formed in the edge cover film F1 by photolithography. The edge cover film F1 with the through hole TH was hence formed.

Next, step S60 and step S70 were performed. A hole injection layer, a hole transport layer, a light-emitting layer including the light-emitting layer EM1 and the light-emitting layer EM2, an electron transport layer, an electron injection layer, and the common electrode CE were formed. The light-emitting layer was vapor-deposited in a desired pattern using a vapor deposition mask for each red subpixel, green subpixel, and blue subpixel. The hole injection layer, the hole transport layer, the electron transport layer, the electron injection layer, and the common electrode CE were vapor-deposited across the entire surface of the display unit 10.

Next, in step S80, a laminate film including a first inorganic film, a second inorganic film, and an organic film interposed between the first and second inorganic films was formed as the sealing layer EF. The first and second inorganic films were formed by CVD. An acrylic resin was formed as an organic film with a thickness of 5 μm to 15 μm by inkjet printing. The projections and depressions formed by, for example, the first depression R1, the through hole TH, and the through hole KH were covered with the first inorganic film and filled up substantially flatly with the organic film.

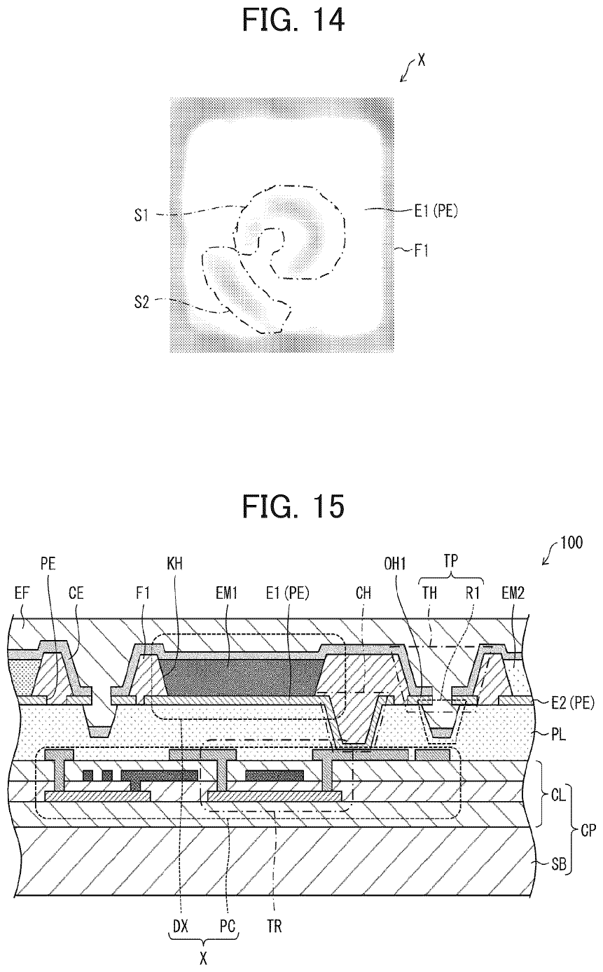

FIG. 14 is a diagram representing a plan-view photograph of a subpixel in accordance with Example 1. Referring to FIG. 14, in the subpixel X in accordance with Example 1, only shadows S1, S2 were observed that were attributable to the base structure such as the circuit layer CL, and no foreign objects were observed that overlapped the first electrode E1 in a plan view. The subpixel X in accordance with Example 1 emitted light in a normal manner.

FIG. 22 is a diagram representing a plan-view photograph of a subpixel in accordance with a comparative example. The comparative example shown in FIG. 22 was manufactured similarly to Example 1, except that there were provided no depressions for capturing foreign objects in the organic insulating film and also that there were provided no through holes overlapping the depressions in a plan view in the edge cover film. Referring to FIG. 22, in the subpixel in accordance with the comparative example, foreign objects FM overlapping the pixel electrode 220 in a plan view, as well as shadows S11, S12 attributable to the base structure, were observed. The subpixel in accordance with the comparative example did not emit light, hence forming a so-called dark spot, and a display unit 210 was found defective. It is inferred that the foreign objects FM caused short-circuiting of the pixel electrode 220 to the common electrode.

### Embodiment 2

A description is given below of other embodiments of the present disclosure. For convenience of description, members of the present embodiment that have the same function as members of the foregoing embodiment are denoted by the same reference numerals, and description thereof is not repeated.

FIG. 15 is a cross-sectional view of an exemplary structure of a display unit in a display device in accordance with an embodiment of the present disclosure. Referring to FIG. 15, the display device 100 in accordance with the present embodiment has, in the display unit 10, an inorganic body OH1 that juts out into an opening of the first depression R1 in a plan view. The inorganic body OH1 may be formed from the same layer as the first electrode E1.

Electrode material does not readily adhere to the face that is hidden behind the inorganic body OH1 when the electrode material is vapor-deposited. Therefore, the common electrode CE can be broken up by the inorganic body OH1. Therefore, the inorganic body OH1 is preferably disposed so that the inorganic body OH1 does not divide the display unit 10 into a plurality of regions in a plan view. When the inorganic body OH1 is provided continuously along the first depression R1, the first depression R1 is preferably disposed so that the first depression R1 does not divide the display unit 10 into a plurality of regions in a plan view. As an example, the depressions, including the first depression R1 and the second depressions R2, are preferably disposed as shown in FIGS. 6 to 8.

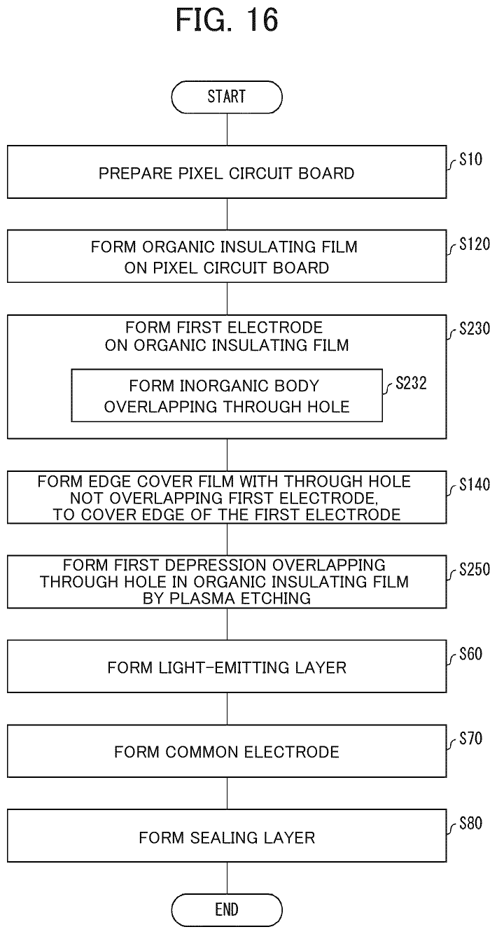

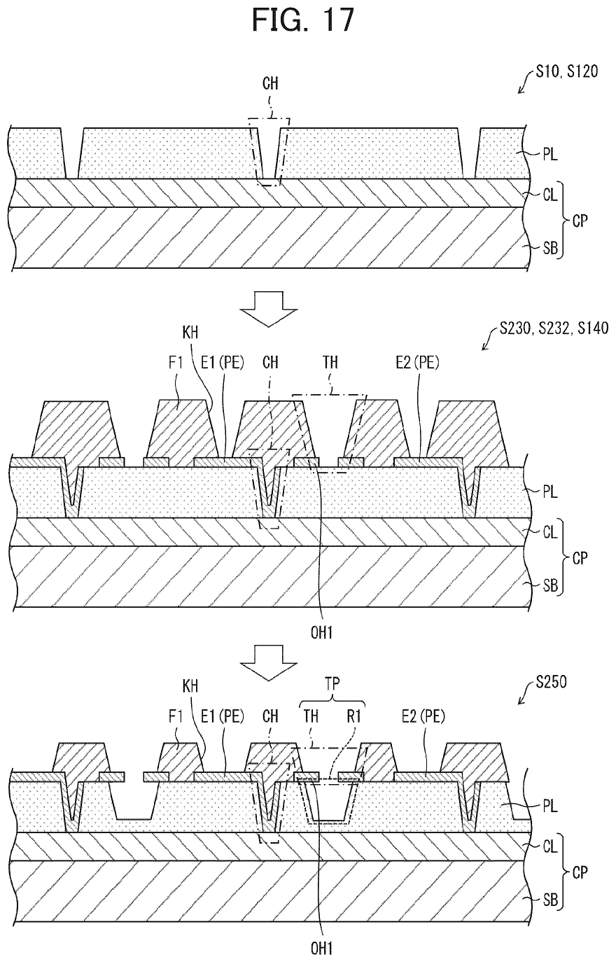

FIG. 16 is a flow chart representing an exemplary method of manufacturing a display device in accordance with an embodiment of the present disclosure. FIG. 17 is a cross-sectional view illustrating an exemplary method of manufacturing a display device in accordance with an embodiment of the present disclosure. Referring to FIGS. 16 and 17, step S10 and step S120 are performed, and subsequently, the first electrode E1 is formed on the organic insulating film PL (step S230). Then, step S140 is performed, and subsequently, the first depression R1 overlapping the through hole TH is formed in the organic insulating film PL (step S250).

The inorganic body OH1 overlapping the through hole TH is formed (step S232) in the step of forming the first electrode E1 (step S230), and the first depression R1 is formed by plasma etching in the step of forming the first depression R1 (step S250). This plasma etching removes the organic insulating film PL overlapping the inorganic body OH1 in a plan view, thereby forming the first depression R1, and also causes the inorganic body OH1 to jut out into the opening of the first depression R1 in a plan view. Step S250 may etch the organic insulating film PL using the inorganic body OH1 as an etching mask. Hence, the first depression R1 self-aligns with the inorganic body OH1, which facilitates increasing the area of the first depression R1 in a plan view. The edge cover film F1 may be formed from a resin film that can be etched by plasma etching.

### Example 2

Referring again to FIGS. 15 to 17, a description is given below of the display device 100 of Example 2 in accordance with the present disclosure. Step S10 was performed similarly to Example 1, and subsequently, in step S120, a commercially available photosensitive polyimide resin was applied to a thickness of 2 μm by spin-coating as the organic insulating film PL. Then, the contact hole CH was formed, to a smaller depth, by photolithography in those sites where the pixel electrodes PE would be formed in the organic insulating film PL.

Next, in step S230, a pixel electrode layer was formed similarly to Example 1, and the plurality of pixel electrodes PE and the inorganic body OH1 were formed from the pixel electrode layer by dry-etching patterning. Next, in step S140, the edge cover film F1 with the through hole TH was formed similarly to Example 1. Next, in step S250, the first depression R1 was formed while decreasing the thickness of the edge cover film F1 by performing dry etching and oxygen plasma ashing across the entire surface. A gaseous mixture of carbon tetrafluoride (CF₄) and oxygen (O₂) was used as an etching gas in the dry etching. The etching time was specified in the range of 0.5 minutes to 300 minutes, and the plasma output was specified in the range of 100 W to 2 kW. In step S250, the contact hole CH was dug to a wiring layer. Subsequently, steps S60, S70, and S80 were performed similarly to Example 1.

The subpixel X of Example 2 emitted light in a normal manner.

### Embodiment 3

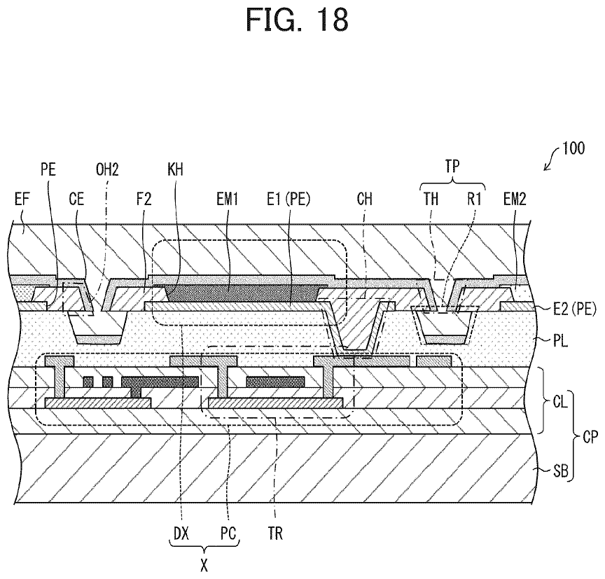

FIG. 18 is a cross-sectional view of an exemplary structure of a display unit in a display device in accordance with an embodiment of the present disclosure. Referring to FIG. 18, the display device 100 in accordance with the present embodiment includes an edge cover film F2 that has a portion OH2 that juts out into the opening of the first depression R1 in a plan view. The portion OH2 may be a part of the edge cover film F2 that surrounds the through hole TH. The edge cover film F2 is an inorganic film and may contain any one or more of, for example, silicon oxide, silicon nitride, and silicon oxynitride.

Electrode material does not readily adhere to the face that is hidden behind the jutting portion OH2 when the electrode material is vapor-deposited. Therefore, the common electrode CE can be broken up by the jutting portion OH2. Therefore, the portion OH2 is preferably disposed so that the portion OH2 does not divide the display unit 10 into a plurality of regions in a plan view. When the portion OH2 is provided continuously along the first depression R1, the first depression R1 is preferably disposed so that the first depression R1 does not divide the display unit 10 into a plurality of regions in a plan view. As an example, the depressions, including the first depression R1 and the second depressions R2, are preferably disposed as shown in FIGS. 6 to 8.

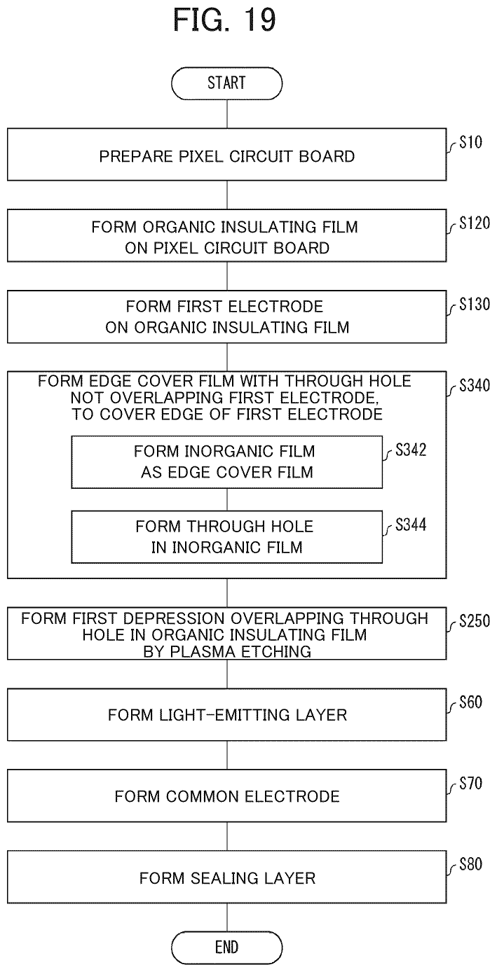

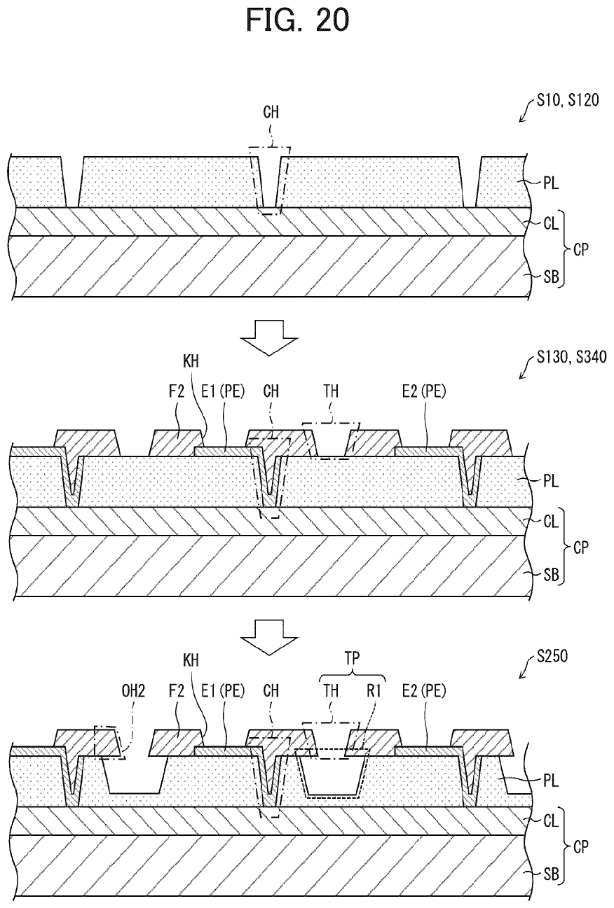

FIG. 19 is a flow chart representing a variation example of a method of manufacturing a display device in accordance with an embodiment of the present disclosure. FIG. 20 is a cross-sectional view illustrating a variation example of a method of manufacturing a display device in accordance with an embodiment of the present disclosure. Referring to FIGS. 19 and 20, step S10, step S120, and step S130 are performed. Subsequently, the edge cover film F2 is formed that has the through hole TH not overlapping the first electrode E1 and that covers an edge of the first electrode E1 (step S340). Then, the first depression R1 overlapping the through hole TH is formed in the organic insulating film PL (step S250).

In the step of forming the edge cover film F2 (step S340), an inorganic film is formed as the edge cover film F2 (step S342), and the through hole TH is formed in this inorganic film by etching (step S344). In the step of forming the first depression R1 (step S250), the first depression R1 may be formed by plasma etching. This plasma etching removes the organic insulating film PL overlapping the portion OH2 in a plan view, thereby forming the first depression R1, and also causes the portion OH2 to jut out into the opening of the first depression R1. Step S250 may etch the organic insulating film PL using the edge cover film F2 as an etching mask. Hence, the first depression R1 self-aligns with the through hole TH, which facilitates increasing the area of the first depression R1 in a plan view.

Subsequently, steps S60, S70, and S80 are performed.

### Example 3

Referring again to FIGS. 18 to 20, a description is given below of the display device 100 of Example 3 in accordance with the present disclosure. Steps S10 and S120 were performed similarly to Example 2, and subsequently, in step S130, a pixel electrode layer was formed similarly to Example 1, and the plurality of pixel electrodes PE were formed from the pixel electrode layer. Next, in step S342, a 200-nm thick film of silicon oxide was formed across the entire surface by sputtering as the edge cover film F2. As the film-forming conditions, argon (Ar) gas was supplied at 190 sccm, oxygen (O₂) gas was supplied at 10 sccm, the ambient gas pressure was set to 0.3 Pa, and the film was formed over 2 to 15 minutes at 200 W to 2 kW power using a silicon oxide target. Next, in step S344, the edge cover film F2 was patterned by dry etching. As the etching conditions, trifluoromethane (CHF₃) was used as the etching gas, the etching gas was supplied at a flow rate of 20 sccm to 200 sccm, and dry etching was conducted for 1 to 15 minutes at 100 W to 2 kW power. After the photoresist was removed in a detaching solution, the substrate was rinsed in an alkali rinsing liquid and dried in an oven.

Next, step S250 was performed similarly to Example 2, and steps S60, S70, and S80 were performed similarly to Examples 1, 2.

The subpixel X of Example 3 emitted light in a normal manner.

The present disclosure is not limited to the description of the embodiments above and may be altered within the scope of the claims. Embodiments based on a proper combination of technical means disclosed in different embodiments are encompassed in the technical scope of the present disclosure. Furthermore, new technical features can be created by combining different technical means disclosed in the embodiments.

1. A display device comprising:
a pixel circuit board;
an organic insulating film formed on the pixel circuit board;
a first electrode formed on the organic insulating film; and
an edge cover film covering an edge of the first electrode, wherein
a first depression at least a part of which does not overlap the edge cover film and the first electrode is formed in the organic insulating film.

2. The display device according to claim 1, wherein the first depression has a bottom positioned in the organic insulating film.

3. The display device according to claim 1, wherein the first depression is tapered downward.

4. The display device according to claim 1, wherein the edge cover film has a through hole that overlaps the first depression.

5. The display device according to claim 4, wherein the through hole is tapered downward.

6. The display device according to claim 4, wherein the first depression has an opening that has a smaller area than does a bottom of the through hole.

7. The display device according to claim 4, wherein the through hole has a sidewall that is flush with a sidewall of the first depression.

8. The display device according to claim 1, wherein the entire first depression does not overlap the edge cover film.

9. The display device according to claim 1, wherein the edge cover film is a resin film.

10. The display device according to claim 1, further comprising an inorganic body that juts out into an opening of the first depression in a plan view.

11. The display device according to claim 10, wherein the inorganic body is provided in a same layer as the first electrode.

12. The display device according to claim 1, wherein the edge cover film has a portion that juts out into an opening of the first depression in a plan view.

13. The display device according to claim 12, wherein the edge cover film is an inorganic film.

14. The display device according to claim 1, wherein the first depression surrounds the first electrode in a plan view.

15. The display device according to claim 1, further comprising a second electrode formed on the organic insulating film, wherein
the edge cover film covers an edge of the second electrode, and
the first depression is positioned between the first electrode and the second electrode in a plan view.

16. The display device according to claim 1, further comprising, in the organic insulating film, a second depression at least a part of which does not overlap the edge cover film and the first electrode, wherein the first depression and the second depression are shaped like a groove.

17. The display device according to claim 16, wherein the first depression and the second depression have different lengths.

18. The display device according to claim 16, or wherein the first depression and the second depression have extension directions that make an angle.

19. The display device according to claim 16, wherein the first electrode is positioned between the first depression and the second depression in a plan view.

20. The display device according to claim 1, further comprising a transistor connecting to the first electrode via a contact hole that runs through the organic insulating film.

21.-26. (canceled)
